(19) United States
(12) Patent Application Publication
(10) Pub. No.: US 2007/0297123 A1
(43) Pub. Date: Dec. 27, 2007

(54) Processing Apparatus and Electronic Device Exterior Material

(75) Inventor: Tatsuya Suzuki, Tokyo (JP)

Correspondence Address: HOGAN & HARTSON L.L.P., 1999 AVENUE OF THE STARS, SUITE 1400, LOS ANGELES, CA, 90067, US

(73) Assignee: OLYMPUS CORPORATION, Tokyo (JP)

(21) Appl. No.: 11/839,429

(22) Filed: Aug. 15, 2007

Related U.S. Application Data
(63) Continuation of application No. 11/273,838, filed on Nov. 14, 2005.
Application No. 11/273,838 is a continuation of application No. PCT/JP05/16071, filed on Aug. 26, 2005.

(30) Foreign Application Priority Data
Mar. 30, 2005 (JP) 2005-098607

(51) Int. Cl. H05K 5/00; B27M 1/02

(52) U.S. Cl. 361/679; 144/359

(57) ABSTRACT

A processing apparatus that processes a wooden piece into a predetermined shape by compression, includes a pair of metal molds that serve to hold and to apply compressing force onto a wooden piece cut out from uncompressed raw wood. At least one of the metal molds has a portion containing iron.

### CROSS-REFERENCE TO RELATED APPLICATIONS

This application is a continuation of PCT international application Ser. No. PCT/JP2005/016071 filed Aug. 26, 2005 which designates the United States, incorporated herein by reference, and which claims the benefit of priority from Japanese Patent Application No. 2005-98607, filed Mar. 30, 2005, incorporated herein by reference.

### BACKGROUND OF THE INVENTION

1. Field of the Invention

The present invention relates to a processing apparatus for processing and forming a wooden piece in a predetermined shape and an exterior material, which is formed from a compressed wooden piece, for an electronic device.

2. Description of the Related Art

In recent years, wood which is natural material attracts attention. With a wide variety of grain patterns, wood products made of wood exhibit individual features depending on positions of the raw wood from which the particular wood products are cut out. Such individual features of each wood product give it a unique quality. In addition, surface damages and discoloration caused by a long-term use create unique textures which tend to evoke warm and familiar feeling in the user. Thus, wood attracts attention as a material for products of uniqueness and taste which cannot be found in products made of synthetic resin or light metals. Techniques for processing wooden pieces are also developing dramatically.

According to one conventionally known technique for processing wooden pieces: a wooden board is softened with water absorption and compressed; the compressed wooden board is cut along a direction substantially parallel with a direction in which the compressing force is applied, whereby a primary fixed product with a sheet-like shape is obtained; and the primary fixed product is deformed into a desired three-dimensional shape under heat and moisture (for example, see Japanese Patent No. 3078452 Publication). Further, according to another conventional technique, a softened wooden board is compressed and temporarily secured in a prepared mold and left in the mold until the wooden board recovers. Thus a wood product with a desired shape can be obtained (see, for example, Japanese Patent Laid-Open No. H11-77619 Publication).

When such a compressed wooden piece is employed as an electronic device exterior material, internal wirings need to be protected by electrical shielding from electromagnetic waves transmitted from outside. For this purpose, a conductive layer is conventionally formed from a thin conductive plate of materials such as brass and applied onto a surface of the compressed wooden piece.

### SUMMARY OF THE INVENTION

A processing apparatus according to one aspect of the present invention, that processes a wooden piece into a predetermined shape via compression, includes a pair of metal molds that serve to hold and to apply compressing force onto a wooden piece cut out from uncompressed raw wood; wherein at least one of the metal molds has a portion containing iron.

An electronic device exterior material according to another aspect of the present invention includes a layer formed from a material containing iron at a predetermined position on a surface of a wooden piece having a three-dimensional shape.

An electronic device exterior material according to still another aspect of the present invention is formed by compression of a wooden piece cut out from uncompressed raw wood in a water vapor atmosphere of a predetermined temperature and pressure with a pair of metal molds, at least one of which has a portion containing iron. In such exterior material, a layer is formed from a material containing iron on a surface of the wooden piece which is brought into contact with the metal mold having the portion containing iron at the compression of the wooden piece by the pair of metal molds.

### BRIEF DESCRIPTION OF THE DRAWINGS

FIG. 1 is an explanatory view of structures of main parts of a processing apparatus according to a first embodiment of the present invention;

FIG. 2 is an explanatory diagram which schematically shows shaping of a wooden piece from uncompressed raw wood;

FIG. 3 is a sectional view along a line A-A shown in FIG. 1;

FIG. 4 is a vertical sectional view of a wooden piece under compression in the processing apparatus according to the first embodiment of the present invention;

FIG. 5 is a perspective view of a structure of an electronic device exterior material according to the first embodiment of the present invention;

FIG. 6 is a sectional view along a line B-B shown in FIG. 5;

FIG. 7 is a perspective view of an external structure of a digital camera to which the electronic device exterior material shown in FIG. 5 is applied;

FIG. 8 is a perspective view of a structure of the electronic device exterior material according to the first embodiment of the present invention where the exterior material of the present invention is employed as the exterior material of the digital camera;

FIG. 9 is a bottom view of a structure of a metal mold employed in a processing apparatus according to a second embodiment of the present invention; and

FIG. 10 is a perspective view of a structure of an electronic device exterior material according to the second embodiment of the present invention where the exterior material of the present invention is employed as the exterior material of the digital camera.

### DETAILED DESCRIPTION OF THE PREFERRED EMBODIMENTS

Hereinafter, exemplary embodiments of the present invention (hereinbelow simply referred to as embodiments) will be described with reference to the accompanying drawings.

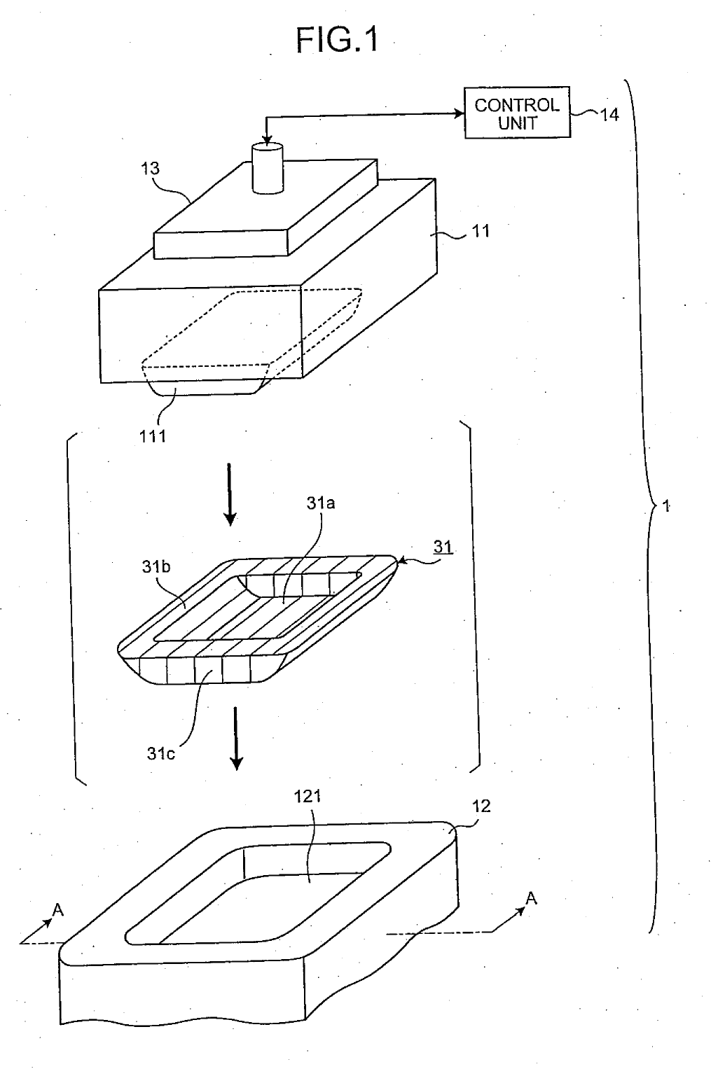

FIG. 1 is an explanatory view of structures of main parts of a processing apparatus according to a first embodiment of the present invention. A processing apparatus 1 shown in FIG. 1 serves to sandwich and compress a wooden piece with use of a pair of metal molds, thereby shaping the wooden piece into a predetermined three-dimensional shape. The processing apparatus 1 includes a pair of metal molds 11 and 12 that sandwich and compress a wooden piece 31 to be processed, a driving unit 13 which drives the metal mold 11 in a vertical direction, and a control unit 14 which performs drive control of the driving unit 13.

The metal mold 11, which applies compressing force to the wooden piece 31 from above at the time of compression, is realized with a material containing iron and has a protrusion 111 which fits an internal surface of the wooden piece 31. The metal mold 12, which applies compressing force to the wooden piece 31 from below at the time of compression, is realized with a material containing aluminum or stainless steel and has a depression 121 which fits an external surface of the wooden piece 31.

The control unit 14 serves to perform drive control of the driving unit 13 by sending a predetermined control signal to the driving unit 13. Here, the metal mold 11 is electrically driven by the driving unit 13 and the control unit 14 as mentioned above. Alternatively, the metal mold 11 and the metal mold 12 may be connected by a screw, and the distance between two molds may be adjusted by manual/automatic tightening/unwinding of the screw, so that one metal mold is made to approach the other metal mold when the screw is being fastened, thereby applying a predetermined compressing force to the wooden piece 31.

A shape of the wooden piece 31 to be processed by the processing apparatus 1 will be described. The wooden piece 31 includes, as shown in FIG. 1, a main plate 31a which has a substantially rectangular surface, two side plates 31b that extend from respective sides of the main plate 31a, the sides being substantially parallel with a lengthwise direction of the main plate 31a, and that form a predetermined angle with the main plate 31a, and two side plates 31c that extend from respective sides of the main plate 31a, the sides being substantially parallel with a breadthwise direction of the main plate 31a, and that form a predetermined angle with the main plate 31a. The wooden piece 31 as a whole is of a substantially bowl-like shape.

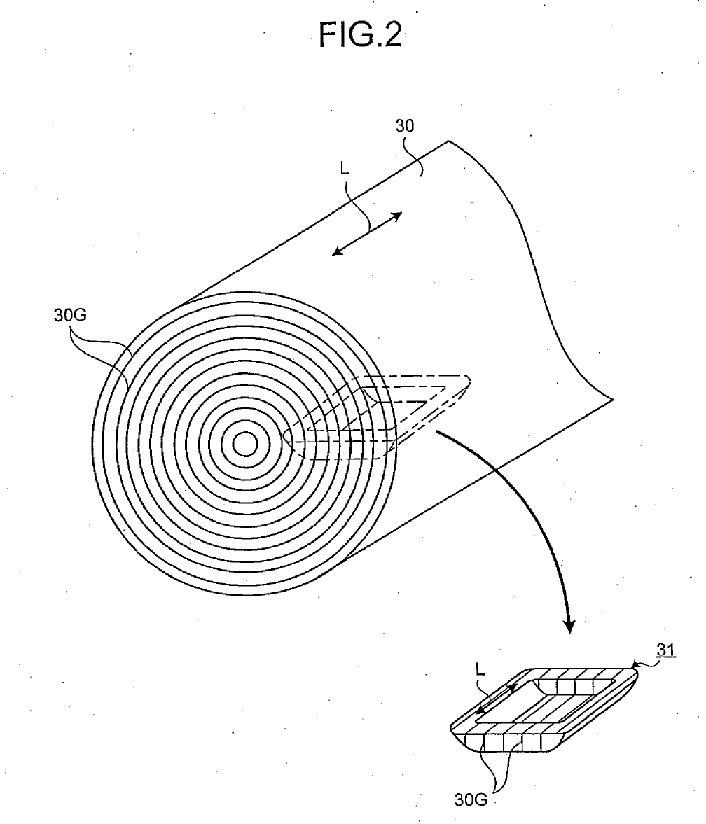

FIG. 2 is an explanatory diagram which schematically shows shaping of the wooden piece 31 from uncompressed raw wood. As shown in FIG. 2, the wooden piece 31 is cut out from the raw wood 30 by a cutting operation or the like so that a direction L of wooden fibers of the wooden piece 31 is substantially parallel with a lengthwise direction of the wooden piece 31. At the shaping, a volume of the wooden piece 31 as cut out is made to be larger than a volume of a finished product by an amount to be decreased in the compression process described later.

Though FIG. 2 illustrates the wooden piece 31 with the main plate 31a having a straight grain surface, the wooden piece 31 can be cut out from the raw wood 30 in different manners. For example, the wooden piece 31 can be alternatively cut out so that the lengthwise direction thereof is substantially parallel with the direction L of wooden fibers of the wooden piece 31 and yet the main plate 31a has a flat grain surface or a surface with intermediate grain pattern of flat grain and straight grain. Generally, desirable grain pattern of the wooden piece varies according to required strength, appearance, or the like. Hence, in the drawings to be referred to in the following description, the grain pattern on the surface of the wooden piece is not particularly shown.

Here, the raw wood 30 employed in the first embodiment may be selected from, for example, Japanese cypress, hiba cedar, paulownia, Japanese cedar, pine, cherry, zelkova, ebony wood, teak, mahogany, and rosewood, as most appropriate for the purpose of use of the processed wood piece. The same is applied similarly to all embodiments of the present invention.

The compression process of the wooden piece 31 performed by the processing apparatus will be described in details. Before the compression process, the cut-out wooden piece 31 is left in a water vapor atmosphere in high temperature and high pressure for a predetermined time period. Thus, the wooden piece 31 absorbs water in excess to be softened. Thereafter, in the same water vapor atmosphere mentioned above, the wooden piece 31 is arranged so that an external surface of the main plate 31a is located over the depression 121 of the metal mold 12. Then, the driving unit 13 is driven under the control of the control unit 14 to lower the metal mold 11 which is attached to a bottom portion of the driving unit 13, thereby sandwiching the wooden piece 31 between the metal molds 11 and 12 to apply a predetermined compressing force onto the wooden piece 31.

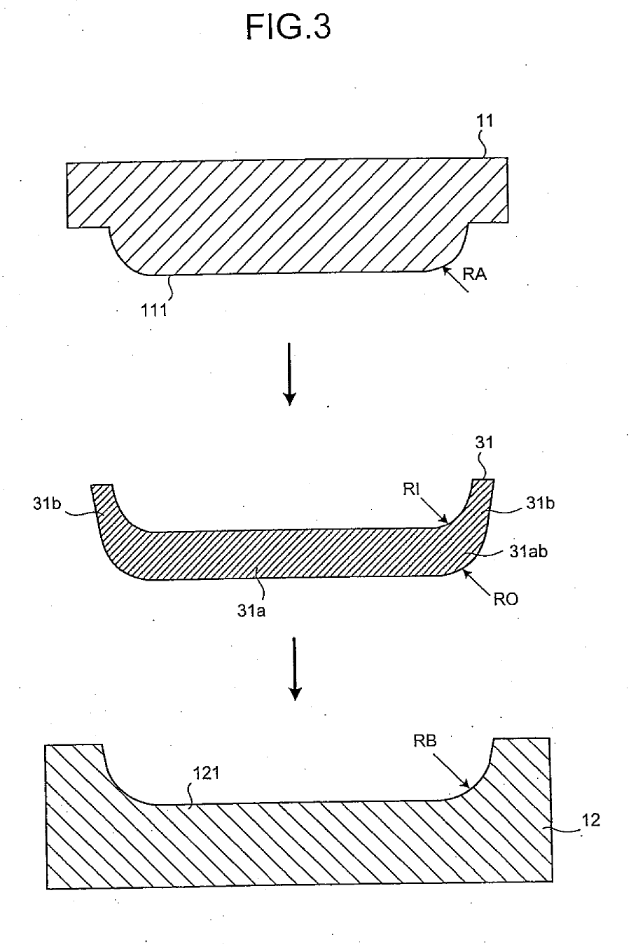

FIG. 3 is a diagram which schematically shows the process of holding and compressing of the wooden piece 31 between the metal molds 11 and 12, and is a sectional view along a line A-A in FIG. 1. As shown in FIG. 3, if the radius of curvature of an internal surface of a curved portion 31ab extending from the main plate 31a to the side plate 31b of the wooden piece 31 is represented as RI, and the radius of curvature of a curved surface, which abuts on the curved portion 31ab, in the protrusion 111 is represented as RA, relation represented as RI>RA needs to stand for appropriate compression of the wooden piece 31. In other words, the wooden piece 31 is shaped out and the protrusion 111 is designed so as to satisfy the above relation.

On the other hand, if the radius of curvature of an external surface of the curved portion 31ab extending from the main plate 31a to the side plate 31b of the wooden piece 31 is represented as RO, and the radius of curvature of a curved surface, which abuts on the external surface of the curved portion 31ab, in the depression 121 is represented as RB, relation represented as RO>RB needs to stand for appropriate compression of the wooden piece 31. In other words, the wooden piece 31 is shaped out and the depression 121 is designed so as to satisfy the above relation.

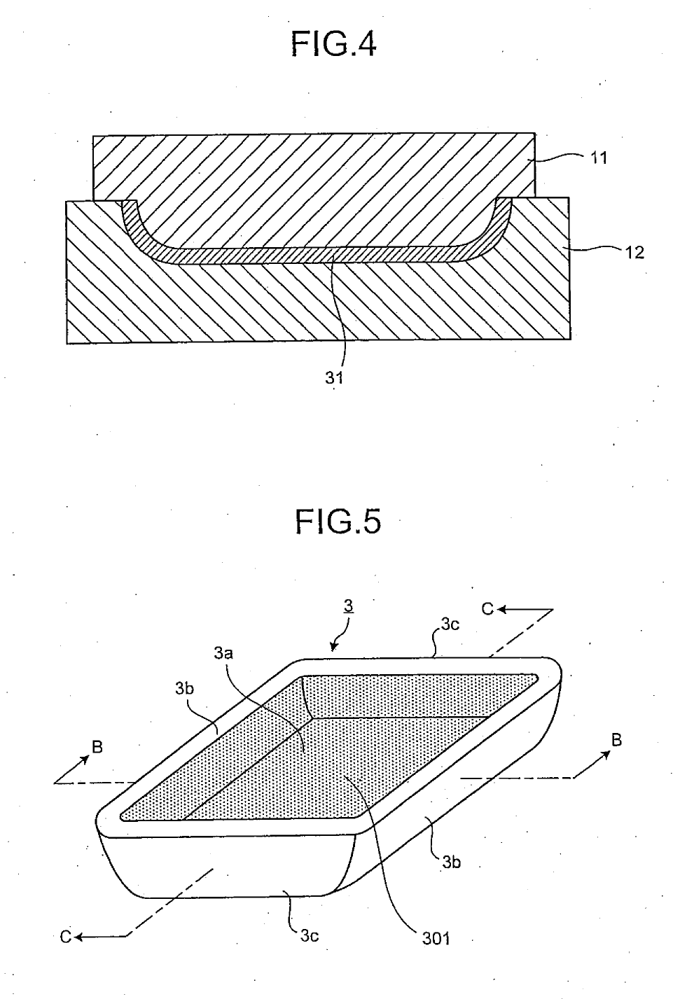

FIG. 4 shows the softened wooden piece 31 arranged in a predetermined position in sandwiched and compressed state, the metal mold 11 lowered by the driving unit 13, and the pair of metal molds 11 and 12 fitting with each other. FIG. 4 is a vertical sectional view of the same section as shown in FIG. 3. The wooden piece 31 is deformed into a three-dimensional shape corresponding to a gap formed between the metal molds 11 and 12, receiving the compressing force in the state shown in FIG. 4 from the metal molds 11 and 12. Here, a thickness of the wooden piece 31 after the compression process is approximately 30% to 50% of the thickness in the uncompressed state as cut out from the raw material 30.

In the compression process, along with the decrease in thickness of the wooden piece 31, metal, such as iron and aluminum, contained in the metal molds 11 and 12 is ionized in the water vapor atmosphere to infiltrate into the surface of the wooden piece 31, and the ionized metal component is fixed therein.

As an example, adhesion of iron to the surface of the wooden piece is described. The wooden piece 31, after being left in the water vapor atmosphere of high temperature and high pressure for a predetermined time period, is softened with absorption of sufficient moisture, and tannin contained inside the wooden piece 31 is in a dissolved state. Further, the moisture contained in the wooden piece 31 in such a state has a sufficient acidity to melt iron in corporation with oxygen in the air. Hence, when the surfaces of the wooden piece 31 and the protrusion 111 are brought into contact, the iron ion reacts with tannin to form metal complex called tannin-iron compound, which adheres to the surface of the wooden piece 31 to form a thin layer. Thus formed layer, containing iron as complex ion, is electrically conductive. On the other hand, if the metal mold 12 is made of a material containing aluminum, a layer of aluminum oxide is formed on the surface of the metal mold 12 as a result of binding of the aluminum ion and oxygen in the atmosphere. Aluminum oxide, however, is not electrically conductive, so it does not form a conductive layer on the surface of the wooden piece 31 even when adhering and transferring to the wooden piece 31.

In the processing apparatus 1 according to the first embodiment, the wooden piece 31 is compressed by the metal mold 11 made of a material containing iron and the metal mold 12 made of a material other than iron in a water vapor atmosphere in high temperature and high pressure. Thus, iron adheres to a surface, which is brought into contact with the metal mold 11, of the wooden piece 31, thereby forming a layer having electrical conductivity, i.e., a conductive layer on the surface of the wooden piece 31.

Conventionally, a separate process is required for the formation of a conductive layer on an insulating material such as wood. For example, a brass plate is arranged and fixed onto a surface of the insulating material in the separate process. Different from such processing, the first embodiment allows for the formation of the conductive layer on the surface of the wooden piece 31 as a part of the compression process, by providing iron in the metal mold 11 which serves to apply compressing force to the wooden piece 31.

After the wooden piece 31 is left in the compressed state as shown in FIG. 4 for a predetermined time period, the metal mold 11 is separated from the metal mold 12 to release the wooden piece 31 from compression and water vapor atmosphere, and then the wooden piece 31 is dried. Thus, the processing of the wooden piece by the processing apparatus 1 ends. FIG. 5 is a perspective view of a structure of an electronic device exterior material according to the first embodiment. An exterior material 3 for an electronic device shown in FIG. 5 includes a main plate 3a which has a substantially rectangular surface, two side plates 3b that extend from respective sides of the main plate 3a, the sides being substantially parallel with a lengthwise direction of the main plate 3a and that form a predetermined angle with the main plate 3a, and two side plates 3c that extend from respective sides of the main plate 3c, the sides being substantially parallel with a breadthwise direction of the main plate 3a and that form a predetermined angle with the main plate 3a. The exterior material 3 is of a substantially bowl-like shape similarly to the wooden piece 31.

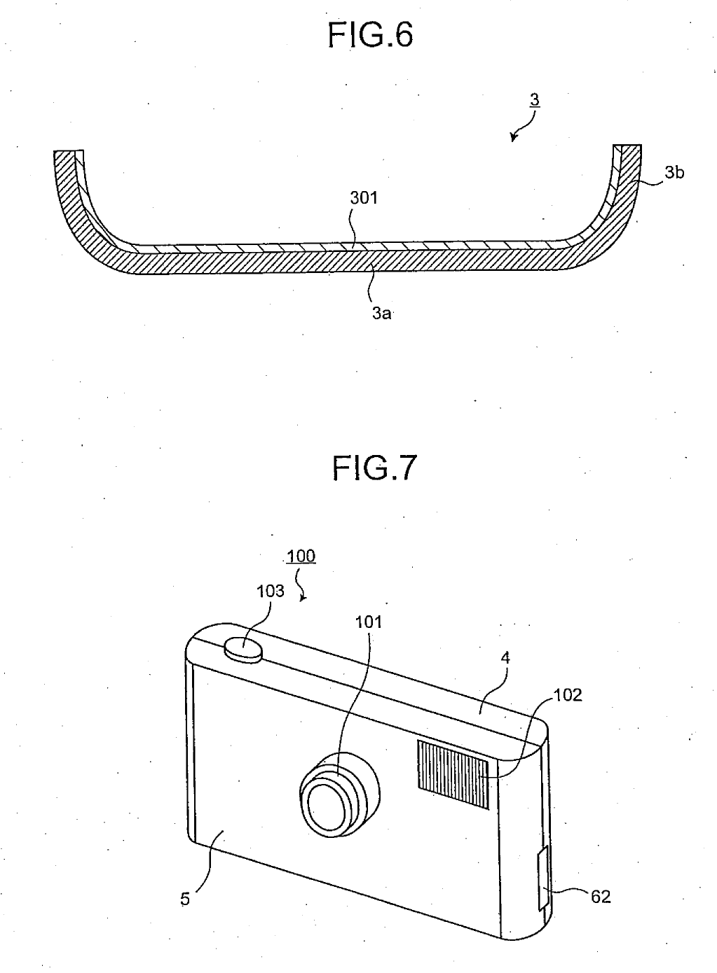

FIG. 6 is a vertical sectional view along a line B-B shown in FIG. 5. As shown in FIG. 6, a conductive layer 301 is formed from a material containing iron and provided on an internal surface extending from the main plate 3a to the respective side plates 3b and 3c of the exterior material 3 for an electronic device. A sectional view along the line C-C of FIG. 5 is substantially the same as the sectional view along the line B-B of FIG. 6 other than the dimension.

FIG. 7 shows an application of the electronic device exterior material according to the first embodiment, and is a perspective view of an external structure of a digital camera having the exterior material processed as described above according to the first embodiment. A digital camera 100 shown in FIG. 7 includes two exterior materials 4 and 5 for an electronic device joined together to form a casing. The exterior material 3 is processed as to have an opening, a cut-out portion or the like as appropriate, to serve as one of the exterior materials 4 and 5. The casing houses an electronic unit, an optical unit or the like (not shown) to realize a function of the digital camera 100. The electronic unit or the optical unit includes a control circuit that performs drive control related to imaging process or the like, a solid-state imaging device such as a charge coupled device (CCD), or a complementary metal-oxide semiconductor (CMOS), and an audio input-output device such as a microphone or a speaker.

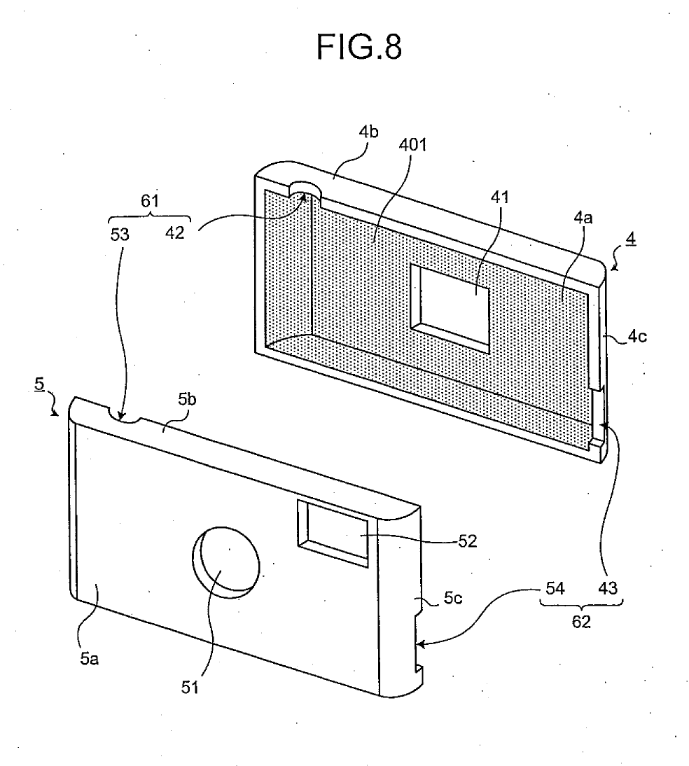

FIG. 8 is a schematic perspective view of a structure of the exterior materials 4 and 5 for an electronic device. A main plate 4a of the exterior material 4 for an electronic device has a rectangular solid opening 41 to expose a display which is implemented by a liquid crystal display, a plasma display, or an organic electroluminescence (EL) display, or the like for displaying image information or textual information. The side plates 4b and 4c of the exterior material 4 for an electronic device have a half-circular cylindrical cut-out portion 42 and a rectangular solid cut-out portion 43, respectively. An internal surface of the exterior material 4 for an electronic device has a conductive layer 401 formed thereon by adhesion of iron.

On the other hand, a main plate 5a of the exterior material 5 for an electronic device includes a circular cylindrical opening 51 to expose an imaging unit 101 having an imaging lens, and a rectangular solid opening 52 to expose a photoflash 102. A side plate 5b of the exterior material 5 for an electronic device has a half-circular cylindrical cut-out portion 53, which forms an opening 61 to expose a shutter button 103 in combination with the cut-out portion 42 of the exterior material 4 for an electronic device. A side plate 5c has a cut-out portion 54, which forms an opening 62 to expose a connection interface (e.g., DC input terminal, USB connection terminal) to an external device, in combination with the cut-out portion 43 of the exterior material 4 for an electronic device. It should be understood that a conductive layer is also formed on an internal surface of the exterior material 5 for electronic device, though not specifically shown in the drawings.

The exterior materials 4 and 5 for electronic device with the above-described structure, being provided with the conductive layer on the internal surface, is capable of shielding electromagnetic waves transmitted from outside and thus preventing false operations of the digital camera 100. In addition, since the wooden piece has grain and unevenness which serve as antislip, operability of the digital camera 100 can be improved.

The openings and the cut-out portions described above may be all at once formed at the cut-out of the wooden piece 31, which serves as a raw material of the exterior material 4 or 5, from the raw wood 30. Alternatively, the opening and the cut-out portion may be formed via cutting, punching, or the like, after the compression process of the wooden piece 31. Alternatively, further opening may be provided at an appropriate position to attach a finder or to expose an operation key through which the user can input an operation instruction signal. Still alternatively, an audio output hole may be provided at an appropriate position to output sounds generated by a speaker embedded in the digital camera 100.

The electronic device exterior material according to the first embodiment can be applied as an exterior material to various electronic devices other than a digital camera, for example, a portable communication terminal such as a portable telephone, a personal handyphone system (PHS) or a personal digital assistant (PDA), a portable audio device, an IC recorder, a portable television, a portable radio, remote controls for various home appliances, and a digital video. More preferably, the thickness of the exterior materials 4 and 5 applied to these electronic devices is approximately 1.6 millimeters (mm).

According to the first embodiment of the present invention as described above, at least one of the pair of metal molds that serve to hold and compress the wooden piece cut ott from the uncompressed raw wood is made of a material containing iron. Thus, a conductive layer can be readily provided economically and with a few processes on the wooden piece to be processed.

Further, according to the first embodiment, the metal component of the metal mold comes to adhere to the surface of the wooden piece in a water vapor atmosphere in high temperature and high pressure, thereby causing modification of the surface. Thus, the hardness of the surface of the wooden piece can be enhanced. Though in the first embodiment, the entire metal mold 11 is made of a material containing iron, as far as a portion of the metal mold 11 brought into contact with the wooden piece 31 contains iron, such material may be employed, for example, only for the protrusion 111, or only for a surface of the protrusion 111.

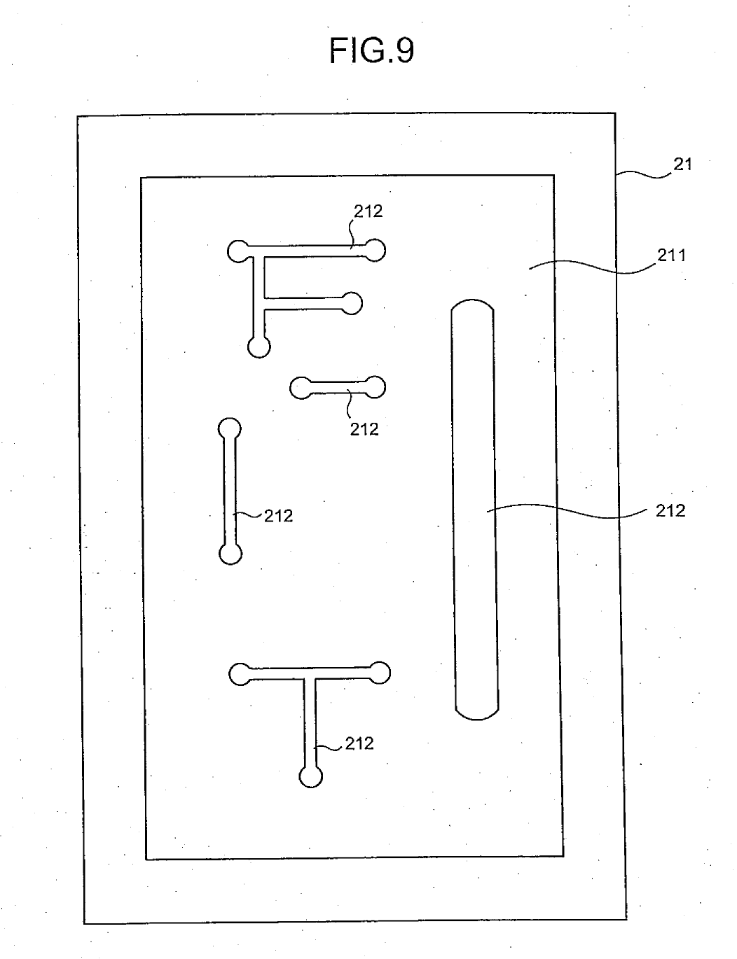

According to a second embodiment of the present invention, a conductive layer having a predetermined design (pattern) is provided on the surface of the wooden piece in the compression process of the wooden piece. FIG. 9 is a bottom view of a structure of a bottom portion of a metal mold employed in a processing apparatus according to the second embodiment. The metal mold 21 shown in FIG. 9 corresponds to the metal mold 11 described with reference to the first embodiment, and has a protrusion 211 to fit the internal surface of the wooden piece 31. On a bottom surface of the protrusion 211, conductive layer forming portions 212 are provided from a material containing iron. A surface of the conductive layer forming portions 212 smoothly leads to a surface of the protrusion 211 and both surfaces form a common plane (or a common curved surface).

A structure of the processing apparatus other than the structure of the metal mold 21 is the same as the structure of the processing apparatus 1 according to the first embodiment. Further, a method of processing the wooden piece by the processing apparatus according to the second embodiment is similar to the method described according to the first embodiment. When the wooden piece is compressed in a water vapor atmosphere in high temperature and high pressure, iron contained in the conductive layer forming portions 212 adheres to the wooden piece on a surface thereof that comes into contact with the conductive layer forming portions 212, thereby forming a conductive layer.

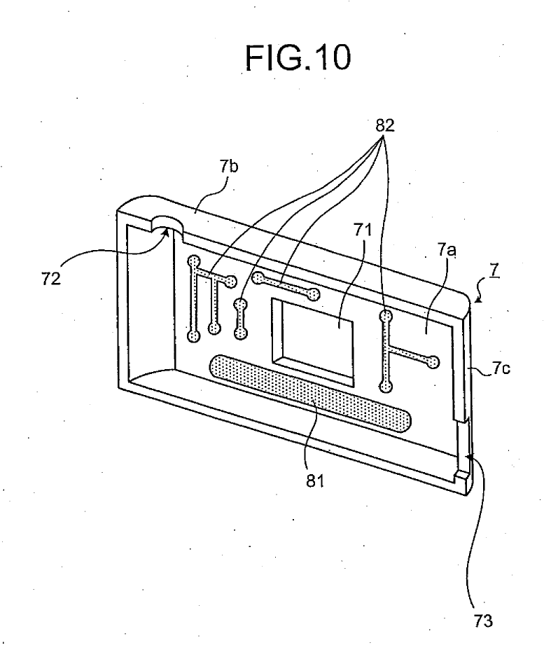

FIG. 10 is a perspective view of a structure of an electronic device exterior material manufactured by the processing apparatus according to the second embodiment. Here, the exterior material is applied to a digital camera as an exterior material thereof. An exterior material 7 for an electronic device shown in FIG. 10 corresponds to the exterior material 4 for an electronic device according to the first embodiment, and serves to cover a back side of the digital camera. The exterior material 7 includes an opening 71 to expose a display, a cut-out portion 72 to expose a shutter button, and a cut-out portion 73 to expose a connection interface.

The internal surface of the exterior material 7 abuts to the protrusion 211 of the metal mold 21 mentioned above in the compression process. Hence, a conductive layer is formed on a portion of the exterior material 7 which is in contact with the conductive layer forming portions 212 provided on the bottom surface of the protrusion 211 during compression. The conductive layer includes a ground line 81 which serves as a conductive path to provide a common reference potential to various electronic units housed in the casing formed by the exterior material 7, and a plurality of electric current lines 82 which serve as conductive paths to connect various electronic units with each other.

The ground line 81 is formed in a substantially rectangular shape which has a long side along the lengthwise direction of the internal surface of the main plate 7a, so that the ground line 81 can be readily connected to plural electronic units. On the other hand, the plural electric current lines 82 are formed as to correspond to locations where respective electronic units are arranged in the casing. Thus, the conduction pattern formed by the conductive layer on the internal surface of the exterior material 7, in other words, the conduction pattern formed by the ground line 81 and the electric current lines 82 changes depending on the arrangement of electronic units housed in the casing formed by the exterior material 7. Hence, the conductive layer forming portions 212 of FIG. 9 or the ground line 81 and the electric current lines 82 of FIG. 10 is only an illustrative example.

Desired insulation characteristics are secured with the ground line 81 and the electric current lines 82 arranged away from the electronic units by a predetermined insulation distance. Alternatively, an additional insulator may be provided to secure insulation if necessary. Further, the electronic unit may be connected to the ground line 81 or the electric current lines 82 via soldering of a tip of a lead wire of the electronic unit to the ground line 81 or to the electric current lines 82. Alternatively, the tip of the lead wire may be arranged as to protrude toward the ground line 81 or the electric current lines 82 so that the tip contact therewith in a non-fixed manner.

According to the second embodiment as described above, similarly to the first embodiment, the conductive layer can be readily and economically provided with a few processes to the wooden piece to be processed.

Further, according to the second embodiment, with the provision of the conductive layer forming portion, which has a predetermined pattern and is made of a material containing iron, on a portion of the surface of the metal mold, the conductive layer (conduction pattern) such as the ground line and the electric current line can be formed on the surface of the wooden piece simultaneously with the compression of the wooden piece.

Though the first and the second embodiments are described as exemplary embodiments of the present invention, the present invention should not be limited thereto. For example, the pair of metal molds may be made of material containing iron. Then, one metal mold that contacts with the external surface of the wooden piece may be formed as to contain iron uniformly, whereas another metal mold that contacts with the internal surface of the wooden piece may be formed as the metal mold 21 according to the second embodiment. Thus, the electromagnetic shield can be formed on the external surface while the ground line, electric current line, or the like can be formed on the internal surface.

Though the wooden piece is cut out from the raw wood in a similar shape to the shape of finished product after the compression, the wooden piece may be cut out from the raw wood in a planar shape, and compressed and processed into a predetermined three-dimensional shape.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-8. (canceled)

9. A processing method for processing a wooden piece into a predetermined shape by compression, the processing method comprising:
sandwiching and applying compressing force onto a wooden piece cut out from uncompressed raw wood by a pair of metal molds, where in
at least one of the metal molds has a portion containing iron.

10. The processing method according to claim 9, wherein one of the metal molds has a portion containing iron, the other of the metal molds has a portion containing one of aluminum and stainless steel.

11. The processing method according to claim 9, wherein a surface of the metal mold having the portion containing iron which is to be brought into contact with the wooden piece has a predetermined pattern, and a portion of the predetermined pattern contains iron.

12. The processing method according to claim 11, wherein one of the metal molds has a portion containing iron, the other of the metal molds ha a portion containing one of aluminum and stainless steel.

13. An electronic device exterior material comprising a layer formed from a material containing iron at a predetermined position on a surface of a wooden piece having a three-dimensional shape.

14. The electronic device exterior material according to claim 13, wherein the layer formed from the material containing iron has a predetermined pattern on the surface of the wooden piece.

15. An electronic device exterior material formed by compression of a wooden piece cut out from uncompressed raw wood in a water vapor atmosphere of a predetermined temperature and pressure with a pair of metal molds, at least one of which has a portion containing iron, wherein
a layer is formed from a material containing iron on a surface of the wooden piece which is brought into contact with the metal mold having the portion containing iron at the compression of the wooden piece by the pair of metal molds.

16. The electronic device exterior material according to claim 15, wherein the layer formed from the material containing iron has a predetermined pattern on the surface of the wooden piece.
